(19) United States
(12) Patent Application Publication
(10) Pub. No.: US 2026/0150417 A1
(43) Pub. Date: May 28, 2026

(54) IMAGE SENSING DEVICE

(71) Applicant: SK hynix Inc., Icheon-si (KR)

(72) Inventor: Seung Hwan CHOI, Icheon-si (KR)

(21) Appl. No.: 19/053,305

(22) Filed: Feb. 13, 2025

(30) Foreign Application Priority Data
Nov. 28, 2024 (KR) 10-2024-0173018

(51) Int. Cl. H10F 39/00

(52) U.S. Cl. CPC H10F 39/8053; H10F 39/8023

(57) ABSTRACT

An image sensing device is provided to include a substrate in which a first pixel region, a second pixel region, and a non-pixel region between the first and second pixel regions are defined; an insulating layer disposed on the substrate; a first grid structure disposed on the insulating layer and in the non-pixel region; a second grid structure disposed on a lateral surface of the first grid structure and including an organic material; and a first color filter disposed over the insulating layer of the first pixel region and configured to transmit light in a first color and absorb light in other colors, and a second color filter disposed over the insulating layer of the second pixel region and configured to transmit light in a second color different from the first color and absorb light in the first color and other colors.

This application claims priority to and the benefit of Korean Patent Application No. 10-2024-0173018, filed on Nov. 28, 2024, the disclosure of which is incorporated herein by reference in its entirety.

### TECHNICAL FIELD

Embodiments of the disclosed technology relate to an image sensing device.

### BACKGROUND

With development of information and communication industry and digitalization of electronic devices, image sensors with improved performance are being used in various fields such as digital cameras, camcorders, mobile phones, PCS (personal communication systems), game devices, security cameras, and medical micro cameras. Typically, an image sensor has a pixel region including a photodiode and a peripheral region. A unit pixel includes a photodiode and a transfer transistor. The transistor is arranged between the photodiode and a floating diffusion region to transfer charges generated by the photodiode to the floating diffusion region.

### SUMMARY

Some implementations of the disclosed technology provide an image sensing device having improved sensing efficiency of sub-pixels.

Some implementations of the disclosed technology provide an image sensing device having improved cross-talk of sub-pixels.

In one aspect, an image sensing device may include a substrate in which a first pixel region, a second pixel region, and a non-pixel region between the first and second pixel regions are defined, wherein the substrate includes a photoelectric conversion element configured to produce an electrical signal in response to incident light and disposed in each of the first and second pixel regions; an insulating layer disposed on the substrate; a first grid structure disposed on the insulating layer and in the non-pixel region; a second grid structure disposed on a lateral surface of the first grid structure and including an organic material; and a first color filter disposed over the insulating layer of the first pixel region and configured to transmit light in a first color and absorb light in other colors, and a second color filter disposed over the insulating layer of the second pixel region and configured to transmit light in a second color different from the first color and absorb light in the first color and other colors.

In another aspect, a display device is provided to comprise a substrate in which a first pixel region, a second pixel region, a third pixel region, a first non-pixel region between the first pixel region and the second pixel region, and a second non-pixel region between the second pixel region and the third pixel region, a third non-pixel region between the first pixel region and the third pixel region, each of the first pixel region, the second pixel region, and the third pixel region comprising a photoelectric conversion element configured to produce an electrical signal in response to incident light; an insulating layer disposed on the substrate; first grid structures disposed on the insulating layer and in the first non-pixel region, the second non-pixel region, and the third non-pixel region; a second grid structure disposed on a lateral surface of the first grid structure in the first non-pixel region; a third grid structure disposed on a lateral surface of the first grid structure in the second non-pixel region; and a fourth grid structure disposed on a lateral surface of the first grid portion in the third non-pixel region.

In another aspect, a display device is provided to include a substrate including a first pixel region, a second pixel region, and a non-pixel region between the first pixel region and the second pixel region, each of the first pixel region and the second pixel region comprising a photoelectric conversion element configured to produce an electrical signal in response to incident light; an insulating layer disposed on the substrate; a first grid structure disposed on the insulating layer and in the non-pixel region; a second grid structure disposed on a lateral surface of the first grid structure, the second grid structure including a material same as the first grid structure; a third grid structure disposed on the other lateral surface of the first grid structure; and a first color filter disposed over the insulating layer of the first pixel region and configured to transmit light in a first color and absorb light in a second color and a third color that are different from the first color, and a second color filter disposed over the insulating layer of the second pixel region and configured to transmit light in the second color and absorb light in the first and third colors.

According to the embodiments, in the non-pixel region, there may be provided the first grid portion on the insulating layer, the second grid portion on the lateral surface of the first grid portion, the first filter configured to transmit the first light on the insulating layer of the first pixel region and absorb the second light and the third light, and the second color filter configured to transmit the second light on the insulating layer of the second pixel region and absorb the first light and the third light. The second grid portion may be disposed on one lateral surface and the other lateral surface of the first grid portion. In the first pixel region, the first light having transmitted the second grid portion may be received after reflected by the first grid portion. In the second pixel region, the second light having transmitted the second grid portion may be received after reflected by the first grid portion. Accordingly, the embodiments may improve sensing efficiency of sub pixels.

Furthermore, according to the embodiment, the second grid portion and the color filters (e.g., the first color filter and the second color filter) may include different materials, respectively. The absorptivity of the second grid portion for the first light may be lower than that of the first color, and the absorptivity of the second grid portion for the second light may be lower than that of the second color filter. Due to that, the first light and the second light, which respectively have passed through the second grid portion, may be reflected by the first grid portion without being lost, and may be received by the photoelectric conversion element of each pixel region. Accordingly, the sensing efficiency of the sub-pixels may be improved.

Still further, according to the embodiments, the first grid portion may be disposed in the non-pixel region, thereby improving crosstalk between adjacent sub-pixels.

### BRIEF DESCRIPTION OF THE DRAWINGS

FIG. 1 is a block view of a shotting system based on some implementations of the disclosed technology.

FIG. 2 shows the image sensing device shown in FIG. 1.

FIG. 3 is a plan view showing a pixel array shown in FIG. 2 based on some implementations of the disclosed technology.

FIG. 4 is a cross-sectional view cut along A-A′ shown in FIG. 3.

FIG. 5 is a cross-sectional view cut along B-B′ shown in FIG. 3.

FIG. 6 is a graph showing a transmittance based on a wavelength of a red color filter, a green color filter, and a blue color filter.

FIG. 7 is a graph showing a transmittance based on a wavelength of a cyan color filter, a yellow color filter, and a magenta color filter.

FIG. 8 is a schematic view that describes an effect generated by a second grid section of the image sensing device based on some implementations of the disclosed technology.

FIG. 9 is a cross-sectional view of a pixel array based on some implementations of the disclosed technology.

FIG. 10 is a plan view of a pixel array based on some implementations of the disclosed technology.

FIG. 11 is a cross-sectional view of a pixel array based on some implementations of the disclosed technology.

FIG. 12 is a cross-sectional view of a pixel array based on some implementations of the disclosed technology.

FIG. 13 is a cross-sectional view of a pixel array based on some implementations of the disclosed technology.

FIG. 14 is a plan view of a pixel array based on some implementations of the disclosed technology.

FIG. 15 is a cross-sectional view of a pixel array based on some implementations of the disclosed technology.

FIG. 16 is a cross-sectional view of a pixel array based on some implementations of the disclosed technology.

FIG. 17 is a cross-sectional view of a pixel array based on some implementations of the disclosed technology.

FIG. 18 is a cross-sectional view of a pixel array based on some implementations of the disclosed technology.

### DESCRIPTION OF SPECIFIC EMBODIMENTS

Description will now be given in detail according to exemplary embodiments disclosed herein, with reference to the accompanying drawings.

Throughout the disclosure, each component can be provided as a single one or a plurality of ones, unless explicitly stated to the contrary. Terms such as “include” or “has” are used herein and should be understood that they are intended to indicate an existence of several components, functions or steps, disclosed in the specification, and it is also understood that greater or fewer components, functions, or steps may likewise be utilized. A singular representation may include a plural representation unless it represents a definitely different meaning from the context. In understanding the components, it should be understood as including the error range even if there is no separate explicit description.

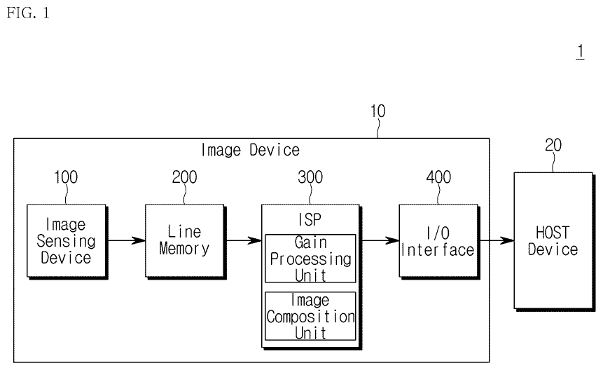

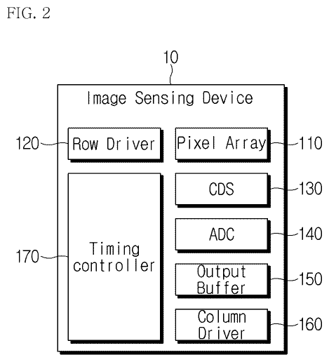

FIG. 1 is a block view of an imaging system according to one embodiment. FIG. 2 shows the image sensing device shown in FIG. 1 in detail.

Referring to FIG. 1, an imaging system 1 may refer to or include a device such as a digital still camera configured to shoot still images or a digital video camera configured to shoot moving images, as well as a device configured to detect motion. For example, an imaging device 10 may be implemented as a digital signal lens reflex DSLR camera, a mirrorless camera, or a mobile phone (especially, a smartphone), but the imaging device 10 is not limited thereto. The imaging device 10 may include a device configured to shoot a subject and generate an image by including a lens and an imaging element.

The imaging system 1 may include an imaging device 10 and a host device 20.

The imaging device 10 may include an image sensing device 100; a line memory 200, ISP (image signal processor) 300, and an input/output interface (I/O interface) 400.

The image sensing device 100 may be or include CIS (Complementary Metal Oxide Semiconductor Image Sensor) configured to convert an optical signal into an electrical signal. The ISP 300 may control the overall operation of the image sensing device 100 such as on/off, operation mode, operation timing, and/or sensitivity. The image sensing device 100 may convert the optical signal into the electrical signal to transmit image data to the line memory 200 based on the control of the ISP 300.

Referring to FIG. 2, the image sensing device 100 may include a pixel array 110, a row driver 120, a correlate double sampler CDS 130, an analog-digital converter ADC 140, an output buffer 150, a column driver 160, and a timing controller 170. Here, each component of the image sensing device 100 may be provided as the example only, and in some implementations, at least some components may be added or omitted.

The pixel array 110 may include a plurality of image pixels disposed in multiple rows and multiple columns. In one embodiment, the plurality of image pixels may be arranged into a two-dimensional array including rows and columns. According to another embodiment, the plurality of image pixels may be arranged into a three-dimensional pixel array. The plurality of image pixels may convert an optical signal into an electrical signal on a pixel basis or a pixel group basis, and image pixels within a pixel group may share at least predetermined internal circuit. The pixel array 110 may receive a pixel control signal including a row selection signal, a pixel reset signal and a transmission signal from the row driver 120, and a corresponding pixel of the pixel array 110 may be activated by the pixel control signal to perform an operation corresponding to the row selection signal, the pixel reset signal, and the transmission signal. Each image pixel may detect incident light by generating a photo charge corresponding to the intensity (or illuminance) of the incident light and generating an electrical signal having a size corresponding to the amount of generated photo charge. For convenience of explanation, an image pixel may also be referred to as a pixel.

The row driver 120 may be configured to activate the pixel array 110 to perform specific operations with respect to pixels provided in a corresponding row based on commands and control signals supplied by the timing controller 170.

In one embodiment, the correlate double sampler 130 may be configured to sequentially sample and hold a reference signal and an image signal, which are provided to each of the multiple column lines from the pixel array 110. That is, the correlative-double sampler 130 may sample and hold the levels of the reference signal and image signal corresponding to each column of the pixel array 110.

The correlate double sampler 130 may transmit the reference signal and image signal of each column to the ADC 140 as a correlate double sampling signal based on a control signal from the timing controller 170.

The ADC 140 may be configured to convert a correlate double sampling signal for each column output from the correlate double sampler 130 into a digital signal, to output image data. In one embodiment, the ADC 140 may convert the correlate double sampling signal generated by the correlate double sampler 130 for each column into a digital signal, and output the converted digital signal.

The ADC 140 may include multiple column counters corresponding to the multiple columns of the pixel array 110, respectively. Each column of the pixel array 110 may be connected to each column counter, and image data may be generated by converting the correlate double sampling signal corresponding to each column into a digital signal using the column counter.

The output butter 150 may be configured to temporarily hold and output image data of each column provided by the ADC 140. The output buffer 140 may temporarily store the image data output from the ADC 140 based on the control signal of the timing controller 170.

The column driver 160 may be configured to select columns of the output buffer 150 based on the control signal of the timing controller 170, and control the output buffer 150 to sequentially output image data temporarily stored in the selected column.

The timing controller 170 may control at least one of the row driver 120, the correlate double sampler 130, the ADC 140, the output buffer 150, and the column driver 160.

The timing controller 170 may provide a clock signal required for the operation of each configuration of the image sensing device 100, a control signal for timing control, and address signals for selecting rows or columns to at least one of the row driver 120, the corelate double sampler 130, the ADC 140, the output buffe 150, and the column driver 160. According to one embodiment, the timing controller 170 may include a logic control circuit, a phase lock loop PLL circuit, a communication interface circuit, etc.

Referring to FIG. 1 again, the line memory 200 may include volatile memory (e.g., DRAM, and SRAM) and/or non-volatile memory (e.g., flash memory).

The line memory 200 may receive and store image data from the image sensing device 100, and transmit the stored image data to the ISP 300 based on the control of the ISP 300.

The ISP 300 may perform image signal processing on the image data stored in the line memory 200. The ISP 300 may reduce noise in the image data, and improve image quality such as gamma correction, color filter array interpolation, color matrix, color correction, color enhancement, lens distortion correction.

To generate HDR image, the ISP 300 may include a gain processing unit 310, and an image compositing unit 320.

The gain processing unit 310 may be configured to determine a gain to be calculated on the image data (e.g., multiplication calculation). The gain processing unit 310 may determine a gain based on the difference in conversion gain between a high conversion gain mode HCG and a low conversion gain LCG mode, and provide the gain to the image compositing unit 320.

Each pixel of the pixel array 110 may be configured to operate in the HCG mode or the LCG mode, and the mode of each pixel may be determined by the intensity (or illuminance) of light incident on each pixel.

The image compositing unit 320 may be configured composite a HDR image corresponding to a high dynamic range, using image data of each pixel operating in the HCG mode and/or image data of each pixel operating in the LCG mode.

The ISP 300 may transmit the image data (e.g., HDR image) processed based on the image signal to the input/output interface 400.

According to another embodiment, the gain processing unit 310 for to generate HDR image and the image compositing unit 320 may be provided not in the ISP 300 but in the image sensing device 100.

The input/output interface 400 may perform communication with the host device 20, and transmit the image data processed by the image signal to the host device 20.

The host device 20 may be or include a processor (e.g., an application processor) configured to process the image data processed based on the image signal received from the imaging device 10, a memory (e.g., a non-volatile memory) configured to store image data, or a display device (e.g., a liquid crystal display LCD) configured to visually output image data.

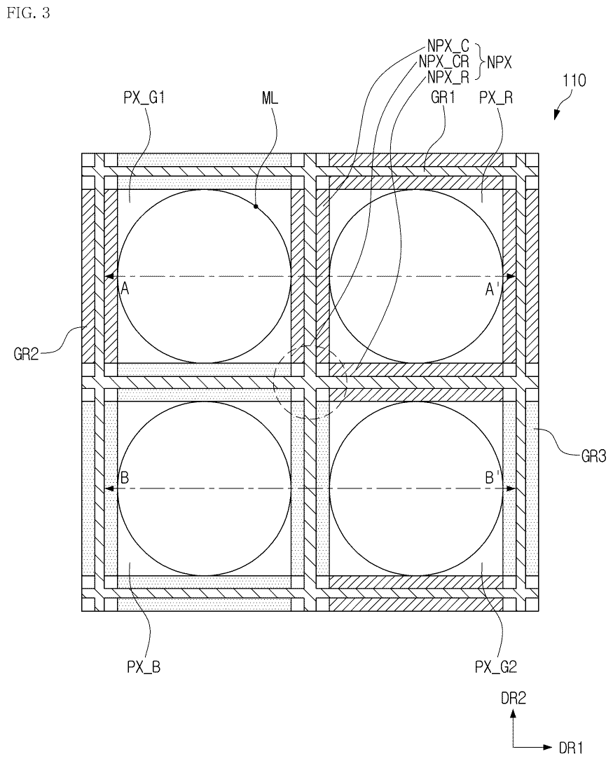

FIG. 3 is a plan view showing a pixel array shown in FIG. 2 based on some implementations of the disclosed technology.

Referring to FIG. 3, the pixel array 110 according to one embodiment may include a plurality of pixels. The plurality of pixels may include a first pixel, a second pixel, a third pixel, and a fourth pixel. Each of the pixels may include a pixel region PX_G1, PX_R, PX_B, or PX_G2 and a non-pixel region NPX. The first pixel may be a green pixel collecting green light, the second pixel may be a red pixel collecting red light, the third pixel may be a blue pixel collecting blue light, and the fourth pixel may be a green pixel collecting green light. The first pixel, the second pixel, the third pixel, and the fourth pixel may include the pixel regions, PX_G1, PX_R, PX_B, and PX_G2, respectively. During the day time, each pixel may receive light in the visible light wavelength range corresponding to its wavelength range. In some implementations, the first pixel, the second pixel, the third pixel, and the fourth pixel may further receive light in the infrared wavelength range. Thus, the peak light reception wavelengths of the first pixel and the fourth pixel may be green wavelengths and infrared wavelengths, the peak light reception wavelength of the second pixel may be red wavelength and infrared wavelength, and the peak light reception wavelength of the third pixel may be blue wavelength and infrared wavelength. During the night time, there is little light in the visible light wavelength range, so each pixel may collect light in the infrared wavelength range for its region. The plurality of pixels may be repeatedly arranged along a first direction DR1 and a second direction DR2, but the arrangement and direction are not limited thereto. A color filter may be disposed in each of the pixels to select the color of the light that transmits through the color filter and different color filters on different adjacent pixels are used to capture the color information in an image carried by the incident light considering the peak wavelength range of the received incident light. For example, green color filters may be disposed in the first pixel and the fourth pixels, respectively, to transmit light in a green color while absorbing light in other colors such as the blue and red colors. A red color filter may be disposed in the second pixel to transmit light in the red color while absorbing light in the green and blue colors, and a blue color filter may be disposed in the third pixel to transmit light in blue while absorbing light in green and red colors. Such color filters may be arranged in a particular color pattern such as a Bayer pattern with a mosaic pattern of two parts in green, one part in red, and one part in blue to represent the colors of a color image.

In several embodiments, the plurality of pixels may further include a fifth pixel receiving white light, but embodiments of the present disclosure are not limited thereto.

The first pixel may include a first pixel region PX_G1 and a non-pixel region NPX surrounding the first pixel region PX_G. The second pixel may include a second pixel region PX_P and a non-pixel region NPX surrounding the second pixel region PX_R. The third pixel may include a third pixel region PX_B and a non-pixel region surrounding the third pixel region PX-B. The fourth pixel may include a fourth pixel region PX-G2 and a non-pixel region surrounding the fourth pixel region PX_G2. For example, four pixels may be grouped and disposed as the group. For example, the first pixel, the second pixel, the third pixel, and the fourth pixel may be arranged in the group of four, as shown in FIG. 3. For example, the pixels may be arranged in a 2×2 array, but the embodiments of the present disclosure are not limited thereto.

For example, the first to fourth pixels may be grouped to form an array (e.g., an array of 2×2 or more for each of the first to fourth pixels). For example, the grouped first pixels may be arranged in groups of four (2×2 array) along a row direction (i.e., a first direction DR1) and a column direction (i.e., a second direction DR2). The grouped second pixels may be arranged in groups of four (2×2 array) along the row direction (i.e., the first direction DR1) and the column direction (i.e., the second direction DR2). The grouped third pixels may be arranged in groups of four (2×2 array) along the row direction (i.e., the first direction DR1) and the column direction (i.e., a second direction DR2), and the grouped fourth pixels may be arranged in groups of four (2×2 array) along the row direction (i.e., the first direction DR1) and the column direction (i.e., the second direction DR2). The grouped first pixels, the grouped second pixels, the grouped third pixels, and the grouped fourth pixels may be disposed in a matrix manner. Thus, the grouped first pixels, the grouped second pixels, the grouped third pixels, and the grouped fourth pixels may be disposed in a matrix manner along the row direction (i.e., the first direction DR1) and the column direction (i.e., the second direction DR2). In some of the embodiments, the pixels of the pixel array 110 may be arranged in a stripe manner. For example, the pixels may be disposed along the first direction DR1 (e.g., red pixels, green pixels, and blue pixels are disposed along the first direction DR1). The pixels arranged along the first direction DR1 may be repeatedly arranged along the first direction DR1 and the second direction DR2.

The non-pixel region NPX may be formed between adjacent pixels. For example, the non-pixel region NPX may be disposed at the boundary between any two of the first pixel, the second pixel, the third pixel, and the fourth pixel.

For example, the non-pixel region NPX may include a first non-pixel region NPX_R extended along the row direction (i.e., the first direction DR1); a second non-pixel region NPX_C extended along the column direction (i.e., the second direction DR2); and a third non-pixel region NPC_CR disposed at the center of the 2×2 array including the first to fourth pixels. In the example as shown in FIG. 3, each of the pixel region of the first to fourth pixels is surrounded by the non-pixel region NPX. For example, when the first pixel PX_GI has four sides, the first non-pixel regions NPX_R are disposed at two of the four sides extending along the row direction, the second non-pixel regions NPX_C are disposed at the remaining two of the four sides extending along the column direction, and the third non-pixel regions NPC_CR are disposed at four vertices of the first pixel.

The pixel array 110 according to one embodiment may further include a light collection pattern ML. a plurality of light collection patterns ML may be provided. The plurality of light collection patterns may be arranged in each of the pixels. The light collection pattern ML may be or include a microlens, but the embodiments of the present disclosure are not limited thereto. In some of the embodiments, the pixel array 110 may include a meta lens layer instead of the light collection pattern ML. For example, the meta lens layer may function to allow light incident from the outside to be received in the pixel regions PX_R, PX_G1, PX-B, and PX_G2.

The pixel array 110 according to one embodiment may further include a grid portion. The grid portion may include a first grid portion GP1. The first grid portion GR1 may have or include a reflective material. For example, the first grid portion GR1 may include a metal material such as aluminum, silver, or tungsten, or an air, but the embodiments of the present disclosure are not limited thereto.

For example, the first grid portion GR1 may be disposed across the first non-pixel region NPX_R and the second non-pixel region NPX_C of the non-pixel region NPX, and may also be arranged in the third non-pixel region NPX_CR.

Th grid portion of the pixel array 110 according to one embodiment may further include a second grid GR2 and a third grid portion GR3. The second grid portion GR2 and the third grid portion GR3 may be disposed in the non-pixel region NPX.

The second grid portion GR2 may be disposed between the first pixel region PX_G1 and the second pixel region PX_R, and between the second pixel region PX_R and the fourth pixel-region PX_G2. The third grid portion GR3 may be disposed between the first pixel region PX-G1 and the third pixel region PX_B, and between the third pixel region PX_B and the fourth pixel region PX_G2. The first pixel region PX-G1 and the fourth pixel region PX-G4 may receive a first light (e.g., green light), the second region PX_R may receive a second light (e.g., red light), and the third pixel region PX_B may receive a third light (e.g., blue light). The second grid portion GR2 may absorb the third light, and may transmit the first light and the second light. The second and third grid portions GR2 and GR4 may include color filters and different materials from each other. The second grid portion GR2 may be or include a yellow color filter and the third grid portion GR3 may be or include a cyan color filter. The second grid portion GR2 may include an organic material, which is different from the first grid portion GR1.

The second grid portion GR2 and the third grid portion GR3 may be arranged in a structure that sandwiches the first grid portion GR1. For example, the second grid portion GR2 may be disposed on two opposite lateral surfaces of the first grid portion GR1 disposed between the pixel region PX_G1 and the pixel region PX_R, and the third grid portion GR3 may be disposed on two opposite lateral surfaces of the first grid portion GR1 disposed between the pixel region PX_B and the pixel region PX_G2.

In FIG. 3, it is shown that the second and third grid portions GR2 and GR3 are not disposed in the third non-pixel region NPX_CR. However, the embodiments of the present disclosure are not limited thereto, and the second and third grid portions GR2 and GR3 may be extended to be disposed even in the third non-pixel region NPX_CR.

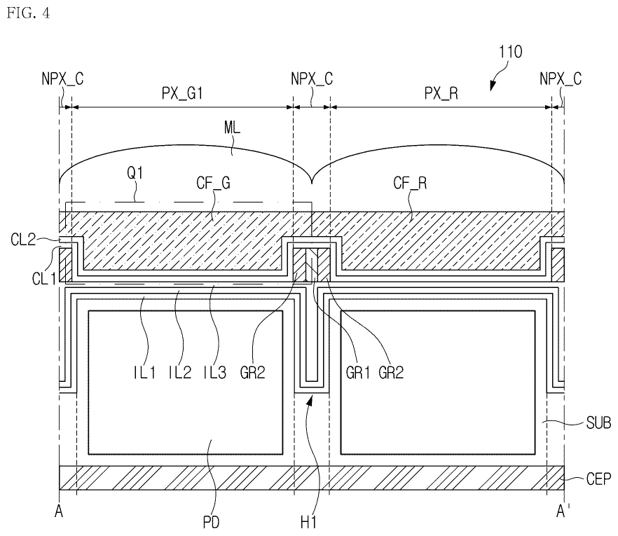

FIG. 4 is a cross-sectional view cut along A-A′ of FIG. 3.

Referring to FIGS. 3 and 4, the pixel array 110 according to one embodiment may include a circuit part CEP; a substrate SUB including a photoelectric conversion element PD on the circuit part CEP; a first groove(H1) formed in the substrate SUB; an insulating layer IL1, IL2 and IL3; a grid portion GR1, GR2 on the insulating layer IL1, IL2 and IL3; a capping layer CL1 and CL2 on the grid portion GR1 and GR2; a color filter CF_G for green and CF_R for red on the capping layer CL1 and CL2; and a light collection pattern ML on the color filter CF_G and CF_R.

The circuit part CEP may be disposed on a lower surface of the substrate SUB, and may include transistors, a wiring layer, and an interlayer insulating layer. The transistors may include an overflow transistor, a transmission transistor, a reset transistor, a driving transistor, and a selection transistor, which are formed on the lower surface of the photoelectric conversion element PD.

The photoelectric conversion element PD may be supported by the circuit part CEP. The photoelectric conversion element PD may function to produce an electrical signal in response to received light including, e.g., a photodiode, a photo transistor, a photo gate, or other photosensitive circuitry capable of converting light into a pixel signal (e.g., a charge, a voltage or a current). The photoelectric conversion element PD may include a single crystal silicon wafer or an epitaxially grown single crystal silicon layer. The photoelectric conversion element PD may have a high refractive index. For example, the refractive index of the photoelectric conversion element PD may have a refractive index of about 2.5 or higher, but the embodiments are not limited thereto. The photoelectric conversion element PD may include a photodiode or photodetector, but the embodiments are not limited thereto.

The substrate is provided to support the photoelectric conversion element PD. For example, the substrate may include a semiconductor substrate having a first surface and a second surface opposite to the first surface. When the light is incident through the first surface of the semiconductor substrate, the circuit part CEP may be disposed on the second surface of the substrate. The photoelectric conversion element PD may be formed by implanting P-type and N-type ions into the substrate. The P-type ions may include boron B ions, and the N-type ions may include phosphorous P and/or arsenic As ions. The photoelectric conversion element PD may be configured to receive incident light and convert an optical signal into an electrical signal. The photoelectric conversion element PD may refer to only a portion corresponding to the pixel region PX_G1 and PX_R, but the embodiments are not limited thereto.

The first groove H1 may be formed in the substrate SUB. The first groove H1 may be formed by recessing the substrate SUB in the thickness direction, e.g., the vertical direction. The first groove H1 may be formed in the non-pixel region NPX. For example, the first groove H1 may be partially recessed from an upper surface of the substrate SUB. In some of the embodiments, the first groove H1 may be formed to completely penetrate from the upper surface to the lower surface of the substrate SUB. A trench portion may be formed in the first groove H1. The first groove H1 may be formed by a suitable process, e.g., through a deep trench process. The trench portion may be formed through the insulating layer IL1, IL2 and IL3 described above. For example, the insulating layer IL1, IL2 and IL3 may include an insulating material. For example, the insulating layer IL1, IL2 and IL3 may include at least one of hafnium oxide (HfO2), silicon oxide (SiOx), or silicon oxynitride (SiON), but the embodiments are not limited thereto. The refractive index of the trench portion may be, for example, about 1.4 to about 2.0, but the embodiments are not limited thereto. The trench portion may be configured to totally reflect the light incident thereon to the photoelectric conversion element PD. In some of the embodiments, the trench portion may include poly silicon Poly Si, and the above-noted insulating material is designed to be formed on a lateral wall of the poly silicon. However, the embodiments are not limited thereto.

In the pixel region PX_G1 and PX_R, the insulating layer IL1, IL2, and IL3 may form an anti-reflection layer. The anti-reflection layer may be in direct contact with the trench portion and the photoelectric conversion element PD. The anti-reflection layer may include the same material as the trench portion. The anti-reflection layer may be formed in the same process as the trench portion and may be integrally connected with the trench portion. The anti-reflection layer may be configured to prevent light incident on the light collection pattern MP from being totally reflected by the photoelectric conversion element PD. To this end, the anti-reflection layer may have a refractive index between the refractive index of the color filter CF_G and CF_R and the refractive index of the photoelectric conversion element PD, but the embodiments are not limited thereto. For example, the refractive index of the anti-reflection layer may be about 1.4 to about 2.0, but the embodiments are not limited thereto.

The first grid portion GR1 may be disposed on the insulating layer IL1, IL2 and IL3. The first grid portion GR1 may be disposed on the non-pixel region NPX (or second non-pixel region NPX_C). The first grid portion GR1 may include a reflective material. For example, the first grid portion G1 may include a metal material but the embodiments are not limited thereto. The first grid portion G1 may include an insulating material with a low refractive index or a structure including an air. The first grid portion GR1 may be disposed in the non-pixel region NPX and configured to totally reflect light incident on the first grid portion GR1. The first grid portion GR1 may prevent light mixing between adjacent pixel regions PX_G1 and PX_R.

The second grid portion GR2 may be disposed on one lateral surface of the first grid portion GR1 (e.g., the side facing PX_G1) and the other lateral surface of the first grid portion GR1 (e.g., the side facing PX_R). The grid portion GR2 may be disposed within the non-pixel region NPX (and/or the second non-pixel region NPX_C). The thickness of the first grid portion GR1 may be the same as that of the second grid portion GR2, but the embodiments are not limited thereto. The second grid portion GR2 may be in direct contact with one lateral surface and the other lateral surface of the first grid portion GR1. The material of the first grid portion GR1 may be different from that of the second grid portion GR2. The second grid portion GR2 may include a light absorbing material. The second grid portion GR2 may absorb a third light (e.g., blue light) and transmit a first light (e.g., green light) and a second light (e.g., red light).

The capping layer CL1 and CL2 may be disposed on the grid portion GR1 and GR2 and the insulating layer IL2, IL2 and IL3. The capping layer CL1 and CL2 may include a first capping layer and a second capping layer CL2, but the embodiments are not limited thereto. The capping layer may be formed as a single layer. The capping layer CL2 and CL2 may include at least one of silicon oxide (SiOx), silicon nitride (SiNx), or silicon oxynitride (SiON). However, the embodiments are not limited thereto. The capping layer CL1 and CL2 may be in direct contact with the upper surface of the first grid portion GR1 and the lateral surface of the second grid portion GR2, and may cover the first and second grid portions GR1 and GR2.

If the first grid portion GR1 includes a structure including an air, the capping layer CL1 and CL2 may be formed above an area where the first grid portion will be formed in the process of forming the first grid portion GR1 having the air structure. Oxygen may be irradiated onto the capping layers CL1 and CL2, and the irradiated oxygen may pass through the capping layers CL1 and CL2, thereby oxidizing a carbon layer filling an area where the first grid portion GR1 is to be formed. The oxidized carbon layer may become carbon dioxide and may be removed to form the first grid portion GR1 having the air structure. Accordingly, the capping layer CL1 and CL2 may include a multiparous layer, but the embodiments are not limited thereto.

A planarization layer (not shown) may be disposed on the capping layer CL1 and CL2, but the embodiments are not limited thereto.

The color filter CF_G and CF_R may be formed on the capping layer CL1 and CL2. The first color filter CF_G may receive light in a green wavelength range (e.g., green light and first light) and an ultraviolet wavelength range, and may block light in the remaining wavelength ranges (e.g., second light and third light). The second color filter CF_R may receive light in a red wavelength range (e.g., red light and second light) and light in an infrared wavelength range, and may block light in the remaining wavelength ranges (e.g., first light and third light).

The light collection pattern ML may be disposed on the color filter CF_G and CF_R. The light collection pattern MP may be configured to collect light incident on the pixel region from the outside. To this end, the light collection pattern ML may have the shape of a convex lens that is convex upward, and may be formed of or include a material with a large difference in a refractive index compared to the air outside. For example, the refractive index of the light collection pattern ML may be about 1.5 to about 1.7, but the refractive index is not limited thereto. As shown in FIG. 4, the light collection pattern ML may be disposed continuously in the pixel region PX_G1 and PX_R and the non-pixel area NPX, and may be formed so that the end of the convex lens shape can be located in the center of the pixel region PX_G1 and PX_R.

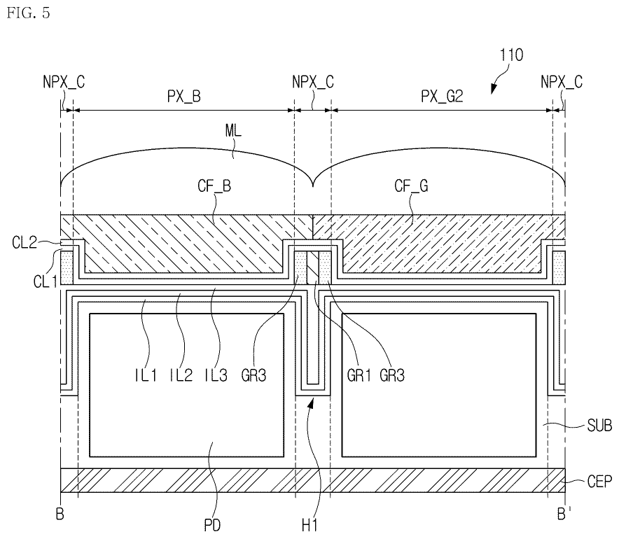

FIG. 5 is a cross-sectional view cut along B-B′ of FIG. 3.

Referring to FIGS. 3 and 5, the pixel array 110 according to one embodiment may further include a third grid portion GR3 on the insulating layer IL1, IL2, and IL3 and a third color filter CF_B for blue.

In the pixel region PX_B and PX_G2, the insulating layer IL1, IL2 and IL3 may form an anti-reflection layer. The insulating layer IL1, IL2, and IL3 is described above in the description of FIG. 4 and detailed description thereof will be omitted.

The third grid portion GR3 may be disposed on each of the lateral surfaces of the first grid portion GR1. For example, the third grid portion GR3 may be disposed on the lateral surface of the first grid portion GR1, which faces PX_B, and the other later surface of the first grid portion GR1, which faces PX_G2. The third grid portion GR3 may be disposed within the non-pixel region NPX (or the second non-pixel region NPX_C). The thickness of the first grid portion GR1 may be the same as that of the third grid portion GR3, but the embodiments are not limited thereto. The third grid portion GR3 may be in direct contact with one lateral surface and the other lateral surface of the first grid portion GR1. The material of the first grid portion GR1 may be different from the material of the third grid portion GR3. The third grid portion GR3 may include a light absorbing material. The third grid portion GR3 may absorb a second light (e.g., red light), and transmit a first light (e.g., green light) and a third light (e.g., blue light).

The capping layer CL1 and CL2 may be in direct contact with the upper surface of the first grid portion GR1 and the lateral surface of the third grid portion GR3, and may cover the first and third grid portions GR1 and GR3.

The color filter CF_B and CF_G may be disposed on the capping layer CL1 and CL2. The third color filter CF_B may receive light in a blue wavelength range (e.g., the blue light or third light) and light infrared wavelength range, and block light in the remaining wavelength ranges (e.g., the first light and the second light).

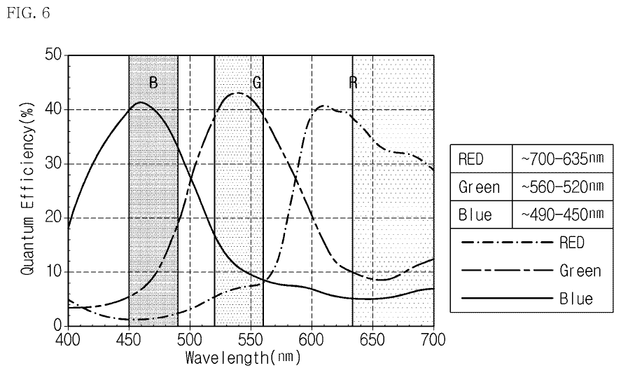

FIG. 6 is a graph showing the transmittance based on the wavelength of a red color filter, a green color filter, and a blue color filter. The horizontal axis of FIG. 6 indicates wavelength, and the vertical axis thereof indicates quantum efficiency. Quantum efficiency may be a concept similar to the transmission of light.

Referring to FIG. 6, each of the red color filter (same as the second color filter in FIG. 4), the green color filter (same as the first color filter in FIG. 4), and the blue color filter (same as the third color filter in FIG. 4) may block the remaining wavelength ranges other than the red wavelength (or red light), the green wavelength range (or green light), and the blue wavelength range (or blue light). The transmittance for red light, green light, and blue light of each of the red color filter (same as the second color filter in FIG. 4), the green color filter (same as the first color filter in FIG. 4), and the blue color filter (same as the third color filter in FIG. 4) may be at a level of about 40%. Thus, the remaining 60% of the red light, green light, and blue light may be absorbed by the red color filter, green color filter, and blue color filter, respectively.

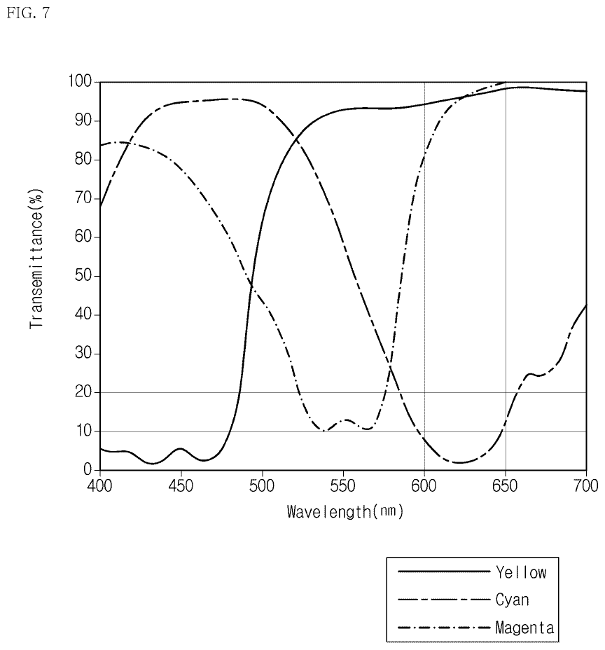

FIG. 7 is a graph showing the transmittance based on the wavelength of a cyan color filter, a yellow color filter, and a magenta color filter. The horizontal axis of FIG. 7 indicates wavelength, and the vertical axis thereof indicates transmittance of light. The cyan color filter may absorb a red wavelength range (or red light) and transmit the remaining wavelength ranges. The yellow color filter may absorb a blue wavelength range (or blue light) and transmit the remaining wavelength range. The magenta color filter may absorb a green wavelength range (or green light) and transmit the remaining wavelength ranges. The cyan color filter may be the same as the third grid portion GR3 of FIG. 5 and the yellow color filter may be the same as the second grid portion GR2 of FIG. 4. As shown in FIG. 7, the cyan color filter, the yellow color filter, and the magenta color filter may have the transmittance for the transmitted light that is higher than the transmittance for the light of the color filters of FIG. 6.

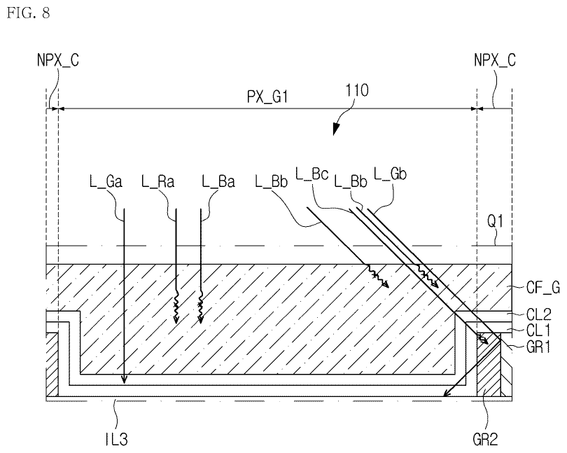

FIG. 8 is a schematic view to describe an effect generated by a second grid section of the image sensing device according to one embodiment. FIG. 8 shows only a schematic diagram of light in the first pixel region PX_G1 and the second non-pixel region NPX_C adjacent to the first pixel region PX_G1. The schematic diagram of the light shown in FIG. 8 may also be applied to other pixel regions PX_G2, PX_B, and PX_R.

Referring to FIG. 8, the first color filter CF_G of the first pixel region PX_G1 may transmit the first light L_Ga incident vertically (not incident on the second non-pixel region NPX_C) and may absorb the second light L_Ra and the third light L_Ba. However, if light is incident obliquely toward the second non-pixel region NPX_C, the light might leak into the adjacent pixel region, which might degrade crosstalk. For example, some of the third light L_Bb may be absorbed by the first color filter CF)G, but other some of the third light (L_Bc may pass through without being absorbed by the first color filter CF_G. however, as described above, the second grid portion GR2 may absorb the third light, and transmit the remaining first and second light. Accordingly, the light L_Bc transmitting through the first color filter CF_G may be absorbed by the second grid portion GR2, which may improve crosstalk.

Most of the second light L_Rb obliquely incident toward the second non-pixel region NPX_C may be absorbed by the first color filter CF_G.

Meanwhile, the first light L_Gb incident obliquely toward the second non-pixel region NPX_C may not be absorbed by the second grid portion GR2 but may be reflected by the first grid portion GR1 including a reflective material, thereby changing a light path back to the first pixel region PX_G1. As described above, the transmittance of the second grid portion GR2 for the first light is higher than the transmittance of the first color filter CF_G for the first light. Accordingly, the light receiving efficiency (or light receiving amount) of the first pixel area PX_G1 for the first light may be improved.

Hereinafter, a pixel array of an image sensing device according to another embodiment will be described. Same numeral references or configurations as those described referring to FIGS. 1 to 8 will be omitted or detailed description thereof will be omitted.

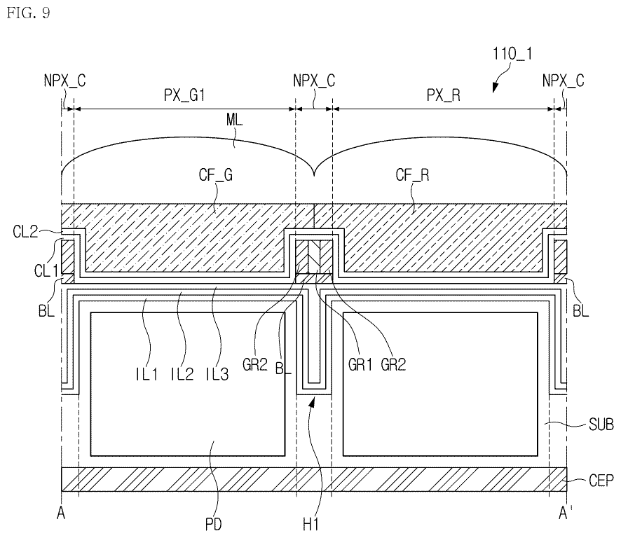

FIG. 9 is a cross-sectional view of a pixel array based on some implementations of the disclosed technology.

Referring to FIG. 9, the pixel array 110_1 according to this embodiment may further include a base layer BL, which is different from the pixel array 110 of FIG. 3.

In the implementations, the base layer BL may be disposed between the first grid portion GR1 and the insulating layer IL1, IL2, and IL3. The width of the base layer BL may be greater than the width of the firs grid portion GR1. The base layer BL may be disposed on a lower surface of the first grid portion GR1 and may be in direct contact with the first grid portion GR1. The base layer BL may include a material having a good adhesion to the insulating layer IL1, IL2, and IL3, compared to the first grid portion GR1. For example, the base layer BL may include a metal material, but the embodiments are not limited thereto.

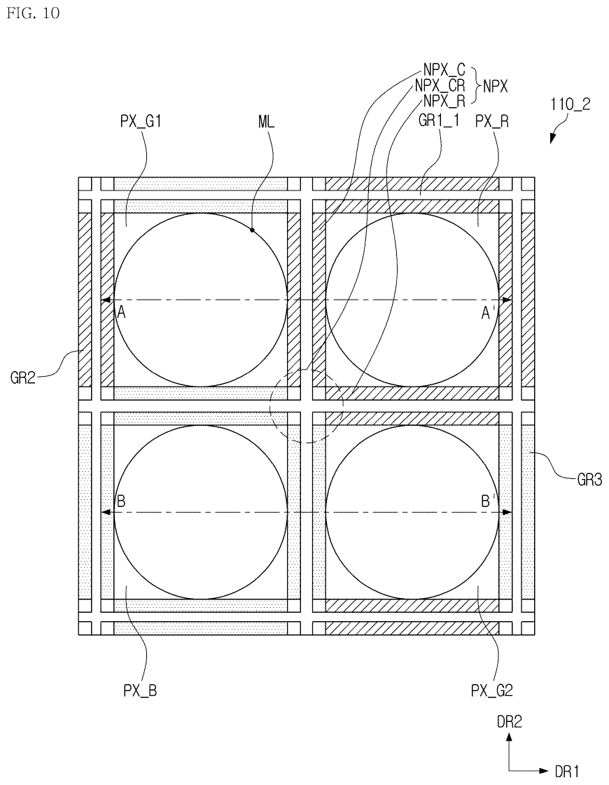

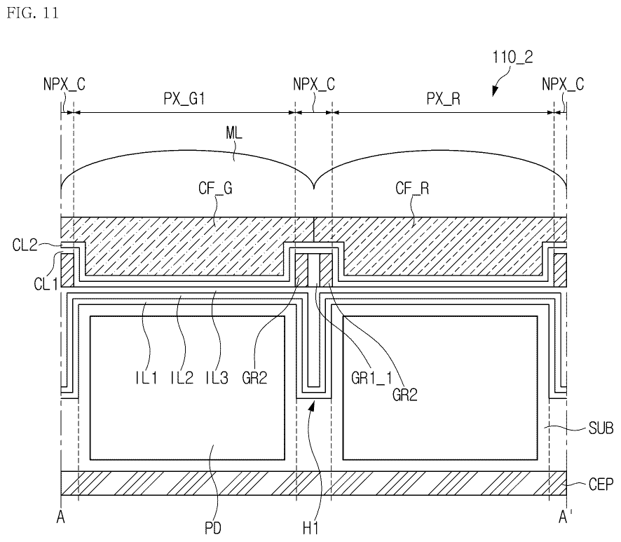

FIG. 10 is a plan view of a pixel array according to another embodiment. FIG. 11 is a cross-sectional view of a pixel array according to another embodiment.

Referring to FIGS. 10 and 11, the first grid GR1_1 of the pixel array 110_2 according to this embodiment may include a low refractive index material (e.g., an air structure), which is different from the pixel array 110 of FIGS. 3 and 4.

In the implementations, if the first grid portion GR1_1 includes the air structure, the capping layer CL1 and CL2 may be formed above an area where the first grid portion GR1 will be formed, in a process of forming the first grid portion GR1_1 including the air structure. Oxygen may be irradiated onto the capping layers CL1 and CL2, and the irradiated oxygen may pass through the capping layers CL1 and CL2, thereby oxidizing a carbon layer filling an area where the first grid portion GR1_1 is to be formed. The oxidized carbon layer may become carbon dioxide and may be removed to form the first grid portion GR1_1 having the air structure. Accordingly, the capping layer CL1 and CL2 may include a multiparous layer, but the embodiments are not limited thereto

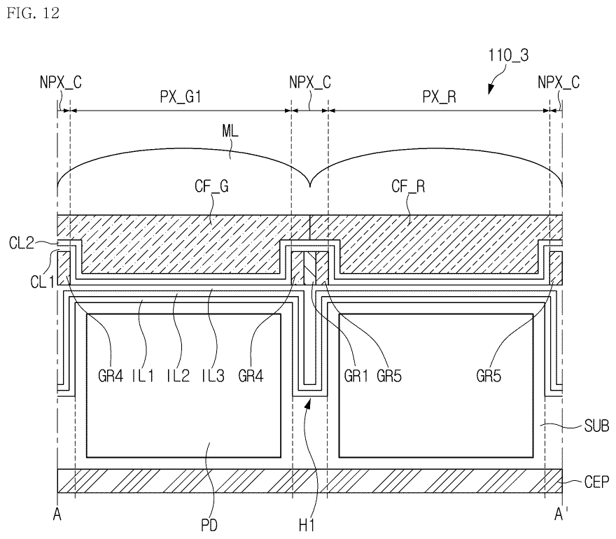

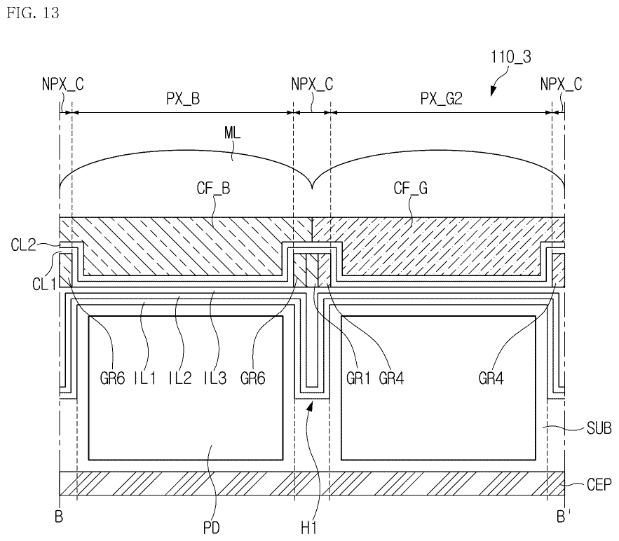

FIG. 12 is a cross-sectional view of a pixel array according to another embodiment. FIG. 13 is a cross-sectional view of a pixel array according to another embodiment.

Referring to FIGS. 12 and 13, in the pixel array 110_3, a fourth grid portion GR4 instead of the second grid portion (see GR2 of FIG. 4) may be disposed in the first pixel (or the green pixel), a fifth grid portion GR5 instead of the second grid portion (see GR2 of FIG. 4) may be disposed in the second pixel (or the red pixel), and a sixth grid portion GR6 instead of the third grid portion (see GR3 of FIG. 5) may be arranged in the third pixel (or the blue pixel), which is different from the pixel array 110 of FIGS. 4 and 5.

More specifically, in the pixel array 110_3 according to this embodiment, the second and third grid portions GR2 and GR3 described in FIGS. 4 and 5 may be omitted, and grid portions GR4, GR5, and GR6 having the same material as the color filters CF_G, CF_R, and CF_B may be placed in their positions.

The fourth grid portion GR4 may include the same material as the first color filter CF_G, the fifth grid portion GR5 may include the same material as the second color filter CF_R, and the sixth grid portion GR6 may include the same material as the third color filter CF_B.

According to this embodiment, among the light incident obliquely on the second non-pixel region NPX_C adjacent to each pixel region PX_G1, PC_R, PX_B, and PX_G2, lights of the other wavelengths that do not need to be received in the pixel region PX_G1, PX_R, PX_B, and PX_G2 by each grid portion GR4, GR5, and GR6 may be absorbed. Accordingly, there is an advantage of further improved crosstalk.

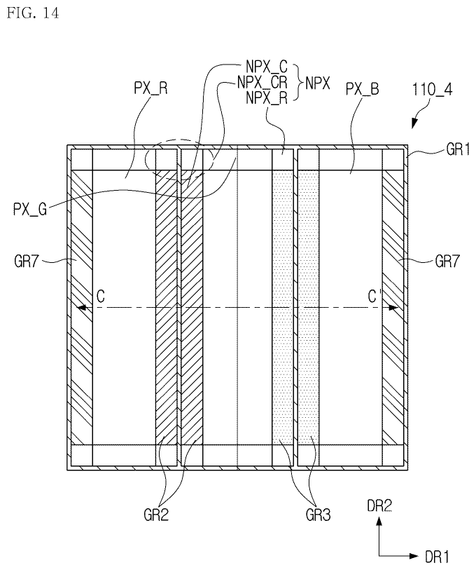

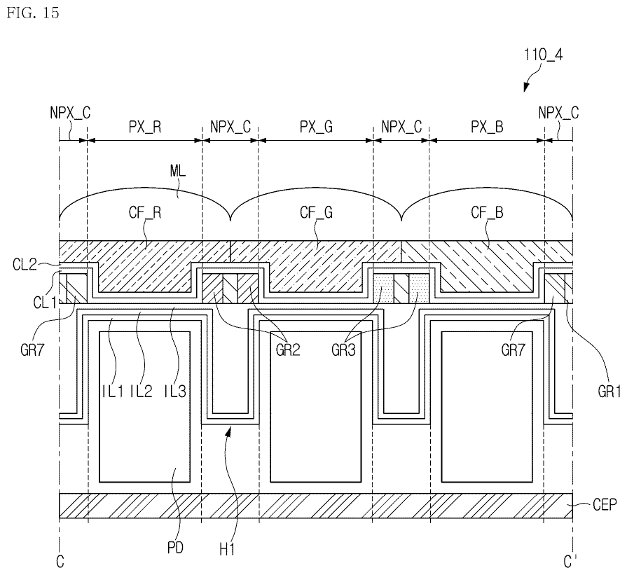

FIG. 14 is a plan view of a pixel array according to another embodiment. FIG. 15 is a cross-sectional view of a pixel array according to another embodiment.

Referring to FIGS. 14 and 15, the pixel array 110_4 according to this embodiment may have a different pixel arrangement from the pixel arrangement shown in FIGS. 3 to 5.

In the implementations, in the pixel array 110_4, a red pixel region PX_R (same as the second pixel region PX_R), a green pixel region )X_G (same as the first pixel region or the fourth pixel region of FIG. 3), and a blue pixel region PX_B (same as the third pixel region of FIG. 3) may be arranged in a strip manner along the first direction DR1. The pixel regions PX_R, PX_G, and PX_G arranged in the stripe manner may be repeatedly disposed along the first direction DR1 and the second direction DR2. A non-pixel region NPX may be disposed between each two of the pixel regions PX_R, PX_G, and PX_B.

The second grid portion GR2 described in FIGS. 3 and 4 may be disposed between the red pixel region PX_R and the green pixel region PX_G. The third grid portion GR3 described in FIGS. 3 and 5 may be disposed between the green pixel region PX_G and the blue pixel region PX_B. meanwhile, the pixel array 110_4 according to this embodiment may further include a seventh grid portion disposed between the blue pixel region PX_B and the red pixel region PX_R. The material of the seventh grid portion GR7 may be different from the material of the color filter CF_R, CF_G, and CF_B and the material of first grid portion GR1. The seventh grid portion GR7 may absorb the first light (or green light), and transmit the second light (or the green light) and the third light (or the blue light). The seventh grid portion GR7 may be a magenta color filter.

The other description is the same as the description of FIGS. 3 to 5, and detailed description will be omitted.

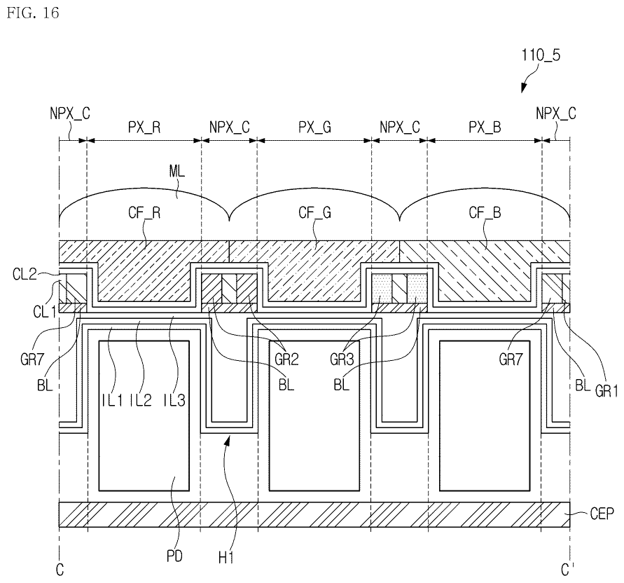

FIG. 16 is a cross-sectional view of a pixel array according to another embodiment.

Referring to FIG. 16, the pixel array 110_5 according to this embodiment may further include a base layer BL, which is different from the pixel array 110_4 of FIG. 15.

In the implementations, the base layer BL may be disposed between the first grid portion GR1 and the insulating layer IL1, IL2, and IL3. The width of the base layer BL may be greater than the width of the first grid portion GR1. The base layer BL may be disposed on a lower surface of the first grid portion GR1 and may be in direct contact with the first grid portion GR1. The base layer BL may include a material having a good adhesion to the insulating layer IL1, IL2, and IL3, compared to the first grid portion GR1. For example, the base layer BL may include a metal material, but the embodiments are not limited thereto.

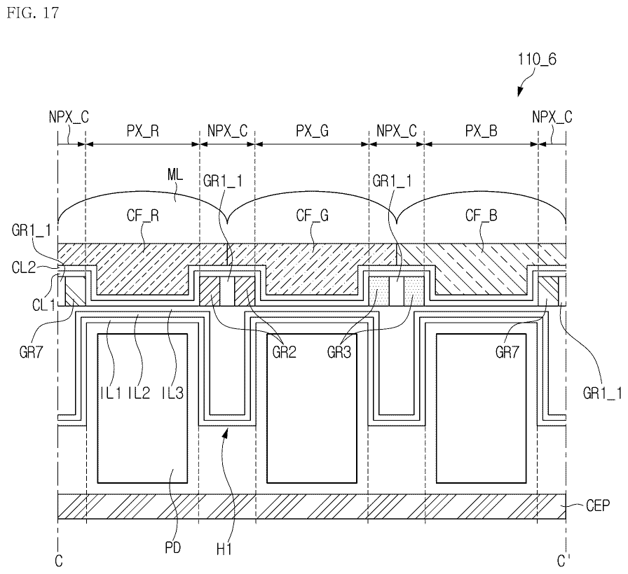

FIG. 17 is a cross-sectional view of a pixel array according to another embodiment.

Referring to FIG. 17, a first grid portion GR1_1 of the pixel array 110_6 according to this embodiment may include a low refractive material (e.g., an air structure), which is different from the pixel array 110_4 of FIG. 15.

In the implementations, if the first grid portion GR1_1 includes an air structure, the capping layer CL1 and CL2 may be formed above an area where the first grid portion GR1_1 will be formed in the process of forming the first grid portion GR1_1 having the air structure. Oxygen may be irradiated onto the capping layers CL1 and CL2, and the irradiated oxygen may pass through the capping layers CL1 and CL2, thereby oxidizing a carbon layer filling an area where the first grid portion GR1_1 is to be formed. The oxidized carbon layer may become carbon dioxide and may be removed to form the first grid portion GR1_1 having the air structure. Accordingly, the capping layer CL1 and CL2 may include a multiparous layer, but the embodiments are not limited thereto

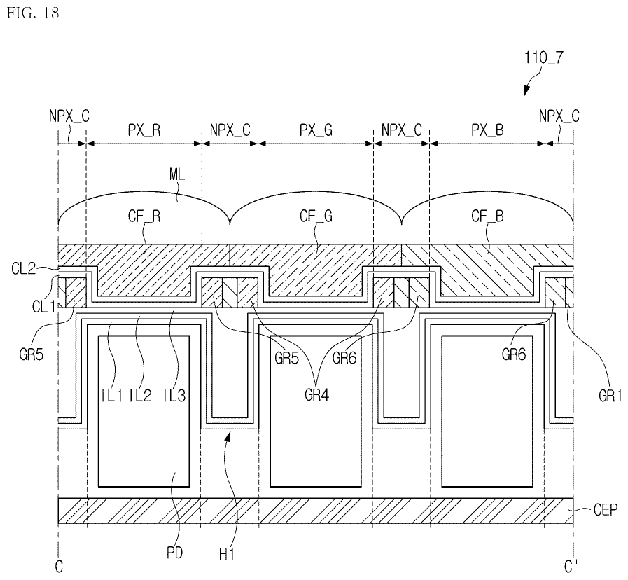

FIG. 18 is a cross-sectional view of a pixel array based on some implementations of the disclosed technology.

Referring to FIG. 18, in the pixel array 110_7 according to this embodiment, a fourth grid portion GR4 instead of the second grid portion (see GR2 of FIG. 4) may be disposed in the first pixel (or the green pixel), a fifth grid portion GR5 instead of the second grid portion (see GR2 of FIG. 4) may be disposed in the second pixel (or the red pixel), and a sixth grid portion GR6 instead of the third grid portion (see GR3 of FIG. 5) may be arranged in the third pixel (or the blue pixel), which is different from the pixel array 110 of FIG. 15.

In the implementations, in the pixel array 110_7, the second and third grid portions GR2 and GR3 described in FIG. 15 may be omitted, and grid portions GR4, GR5, and GR6 having the same material as the color filters CF_G, CF_R, and CF_B may be placed in their positions.

The fourth grid portion GR4 may include the same material as the first color filter CF_G, the fifth grid portion GR5 may include the same material as the second color filter CF_R, and the sixth grid portion GR6 may include the same material as the third color filter CF_B.

According to this embodiment, among the light incident obliquely on the second non-pixel region NPX_C adjacent to each pixel region PX_G1, PC_R, PX_B, and PX_G2, lights of the other wavelengths that do not need to be received in the pixel region PX_G1, PX_R, PX_B, and PX_G2 by each grid portion GR4, GR5, and GR6 may be absorbed. Accordingly, there is an advantage of further improved crosstalk.

The image sensing device according to the various embodiments of the present disclosure may be described as below.

According to one embodiment, an image sensing device may include a circuit portion in which a first pixel region, a second pixel region, and a non-pixel region between the first pixel region and the second pixel region are defined; a substrate provided as a substrate for the circuit portion and including a photoelectric conversion element disposed in each of the first pixel region and the second pixel region; an insulating layer on the substrate; a first grid portion on the insulating layer within the non-pixel region; a second grid portion on a lateral surface of the first grid portion; and a first color filter configured to transmit first light on the insulating layer of the first pixel region and absorb second light and third light, and a second color filter configured to transmit the second light on the insulating layer of the second pixel region and absorb the first light and the third light.

The material of the first grid portion may be different from the material of the second grid portion.

The first grid portion may include a metal material or an air structure.

The second grid portion may include a material different from the material of the first color filter and the material of the second color filter.

The second grid portion may include a light absorbing material and the second grid portion absorbs the third light.

The second grid portion may transmit the first light and the second light.

The second grid portion may be disposed between the first grid portion and the first color filter and between the first grid portion and the second color filter.

The image sensing device may further include a capping layer disposed between the insulating layer and the first color filter and between the insulating layer and the second color filter. The capping layer may cover the first grid portion and the second grid portion.

In the non-pixel region, the substrate may include a first hole recessed from an upper surface, and the insulating layer may be disposed in the first hole.

A third pixel region may be further defined in the circuit portion, and the non-pixel region may be disposed between the first pixel region and the third pixel region. The substrate may further include the photoelectric conversion element disposed in the third pixel region, the first grid portion may be further disposed on the insulating layer of the non-pixel region between the first pixel region and the third pixel region, and the third grid portion may be further disposed on a lateral surface of the first grid portion.

The image sensing device may further include a third color filter configured to transmit the third light on the insulating layer of the third pixel region and absorb the first light and the second light, and the third grid portion may include a material that is different from the material of the first color filter and the material of the third color filter. n

The second grid portion may absorb the second light, and transmit the first light and the third light.

According to another embodiment, an image sensing device may include a circuit portion in which a first pixel region, a second pixel region, a third pixel region, and a non-pixel region between each two of the first to third pixel regions are defined; a substrate on the circuit portion, the substrate comprising a photoelectric conversion element disposed in each of the first pixel region, the second pixel region, and the third pixel region; an insulating layer on the substrate; first grid portions on the insulating layer within a non-pixel region between the first pixel region and the second pixel region, a non-pixel region between the second pixel region and the third pixel region, and a non-pixel region between the third pixel region and the first pixel region; a second grid portion on a lateral surface of the first grid portion within the non-pixel region between the first pixel region and the second pixel region; a third grid portion on a lateral surface of the first grid portion within the non-pixel between the third pixel region and the first pixel regio; and a fourth grid portion on a lateral surface of the first grid portion within the non-pixel region between the third pixel region and the first pixel region.

The display device may further include a first color filter configured to transmit a first light on the insulating layer of the first pixel region and absorb a second light and a third light on the insulating layer of the first pixel region; a second color filter configured to transmit the second light on the insulating layer of the second pixel region and absorb the first light and the third light on the insulating layer of the second pixel region; and a third color filter configured to transmit the third light on the insulating layer of the third pixel region and absorb the first light and a second light.

The material of the first grid portion may be different from the material of the second grid portion.

The first grid portion may include a reflective material.

The second grid portion may be configured to absorb the third light and transmit the first light and the second light.

The third grid portion may be configured to absorb the first light and transmit the second light and the third light.

The fourth grid portion may be configured to absorb the second light and transmit the first light and the third light.

According to a further embodiment, an image sensing device may include a circuit portion in which a first pixel region, a second pixel region, and a non-pixel region between the first pixel region and the second pixel region are defined; a substrate on the circuit portion, and including a photoelectric conversion element disposed in each of the first pixel region and the second pixel region; an insulating layer on the substrate; a first grid portion on the insulating layer within the non-pixel region; a second grid portion on one lateral surface of the first grid portion; a third grid portion on the other lateral surface of the first grid portion; and a first color filter configured to transmit a first light on the insulating layer of the first pixel region and absorb a second light and a third light on the insulating layer of the first pixel region, and a second color filter configured to transmit the second light on the insulating layer of the second pixel region and absorb the first light and the third light on the insulating layer of the second pixel region. The second grid portion may include a material that is the same as the material of the first color filter, and the third grid portion may include a material that is the same as the material of the second color filter.

While various embodiments have been described with reference to the exemplified drawings, variations and improvements of the disclosed embodiments and other embodiments may be made based on what is described or illustrated in this document.

1. An image sensing device, comprising:
a substrate in which a first pixel region, a second pixel region, and a non-pixel region between the first and second pixel regions are defined, wherein the substrate includes a photoelectric conversion element configured to produce an electrical signal in response to incident light and disposed in each of the first and second pixel regions;
an insulating layer disposed on the substrate;
a first grid structure disposed on the insulating layer and in the non-pixel region;
a second grid structure disposed on a lateral surface of the first grid structure and including an organic material; and
a first color filter disposed over the insulating layer of the first pixel region and configured to transmit light in a first color and absorb light in other colors, and
a second color filter disposed over the insulating layer of the second pixel region and configured to transmit light in a second color different from the first color and absorb light in the first color and other colors.

2. The image sensing device of claim 1, wherein the first grid structure and the second grid structure include different materials from each other.

3. The image sensing device of claim 1, wherein the first grid structure comprises at least one of a metal or an air.

4. The image sensing device of claim 1, wherein the organic material of the second grid structure is different from material of the first color filter and material of the second color filter.

5. The image sensing device of claim 1, wherein the second grid structure further comprises a light absorbing material that allows the second grid structure to absorb a third light different from the light in the first color and the light in the second color.

6. The image sensing device of claim 5, wherein the second grid structure is configured to transmit the light in the first color and the light in the second color.

7. The image sensing device of claim 1, wherein the second grid structure is disposed between the first grid structure and the first color filter and between the first grid structure and the second color filter.

8. The image sensing device of claim 1, further comprising:
a capping layer disposed between the insulating layer and the first color filter and between the insulating layer and the second color filter, the capping layer configured to cover the first grid structure and the second grid structure.

9. The image sensing device of claim 1, wherein the substrate further comprises a first hole disposed in the non-pixel region and recessed from an upper surface of the substrate, and the insulating layer is disposed in the first hole.

10. The image sensing device of claim 1, further comprising: a third pixel region disposed in the substrate, an additional non-pixel region disposed between the first pixel region and the third pixel region, the substrate further comprises a photoelectric conversion element disposed in the third pixel region, the first grid structure is further disposed on the insulating layer of the additional non-pixel region between the first pixel region and the third pixel region, and a third grid structure is disposed on a lateral surface of the first grid structure.

11. The image sensing device of claim 10, further comprising:
a third color filter disposed on the insulating layer of the third pixel region and configured to transmit light in a third color different from the first and second colors and absorb light in the first and second colors and in other colors,
wherein the third grid structure comprise a material that is different from material of the first color filter and the organic material of the third color filter.

12. The image sensing device of claim 11, wherein the second grid structure is configured to absorb the second light, and transmit the light in the first color and the light in the third color.

13. A display device, comprising:
a substrate in which a first pixel region, a second pixel region, a third pixel region, a first non-pixel region between the first pixel region and the second pixel region, and a second non-pixel region between the second pixel region and the third pixel region, a third non-pixel region between the first pixel region and the third pixel region, each of the first pixel region, the second pixel region, and the third pixel region comprising a photoelectric conversion element configured to produce an electrical signal in response to incident light;
an insulating layer disposed on the substrate;
first grid structures disposed on the insulating layer and in the first non-pixel region, the second non-pixel region, and the third non-pixel region;
a second grid structure disposed on a lateral surface of the first grid structure in the first non-pixel region;
a third grid structure disposed on a lateral surface of the first grid structure in the second non-pixel region; and
a fourth grid structure disposed on a lateral surface of the first grid structure in the third non-pixel region.

14. The display device of claim 13, further comprising:
a first color filter disposed over the insulating layer of the first pixel region and configured to transmit light in a first color and absorb light in other colors which include a second color and a third color that are different from the first color;
a second color filter disposed over the insulating layer of the second pixel region and configured to transmit light in the second color and absorb light in the first and third colors; and
a third color filter disposed over the insulating layer of the third pixel region and configured to transmit light in the third color and absorb light in the first and second colors.

15. The display device of claim 14, wherein material of the first grid structure is different from material of the second grid structure.

16. The display device of claim 14, wherein the first grid structure comprises a reflective material.

17. The display device of claim 14, wherein the second grid structure is configured to absorb the light in the third color and transmit the light in the first color and the light in the second color.

18. The display device of claim 17, wherein the third grid structure is configured to absorb the light in the first color and transmit the light in the second color and the light in the third color.

19. The display device of claim 14, wherein the fourth grid structure is configured to absorb the light in the second color and transmit the light in the first color and the light in the third color.

20. A display device, comprising:
a substrate including a first pixel region, a second pixel region, and a non-pixel region between the first pixel region and the second pixel region, each of the first pixel region and the second pixel region comprising a photoelectric conversion element configured to produce an electrical signal in response to incident light;
an insulating layer disposed on the substrate;
a first grid structure disposed on the insulating layer and in the non-pixel region;
a second grid structure disposed on a lateral surface of the first grid structure, the second grid structure including a material same as the first grid structure;
a third grid structure disposed on the other lateral surface of the first grid structure; and
a first color filter disposed over the insulating layer of the first pixel region and configured to transmit light in a first color and absorb light in a second color and a third color that are different from the first color, and a second color filter disposed over the insulating layer of the second pixel region and configured to transmit light in the second color and absorb light in the first and third colors.
